(19) United States
(12) Patent Application Publication
(10) Pub. No.: US 2025/0286442 A1
(43) Pub. Date: Sep. 11, 2025

(54) SPINNING ELECTROMOTIVE ASSEMBLY AND METHOD OF OPERATING A SPINNING ELECTROMOTIVE ASSEMBLY

(71) Applicants: ams-OSRAM International GmbH, Regensburg (DE); ams Sensors Germany GmbH, Jena (DE)

(72) Inventors: Clemens MUELLER, München (DE); Markus BUSZ, Kraftsdorf/OT Oberndorf (DE); Tim BOESCKE, Regensburg (DE)

(21) Appl. No.: 18/858,240

(22) PCT Filed: Mar. 28, 2023
(86) PCT No.: PCT/EP2023/057965

§ 371 Date: Oct. 18, 2024

(30) Foreign Application Priority Data
Apr. 21, 2022 (DE) 102022109676.9

(51) Int. Cl. H02K 11/20; H02K 11/33; H02P 29/032

(52) U.S. Cl. CPC H02K 11/20; H02K 11/33; H02P 29/032

(57) ABSTRACT

A spinning electromotive assembly comprises a rotor, which is rotatably supported by a stator and comprises motor coils. A control unit is operable to synchronously reverse the polarity of the motor coils. An optical sensor arrangement is connected to the stator and operable to detect ultraviolet or ultraviolet and/or visible radiation of partial discharges induced in the motor coils when the polarity is reversed.

This disclosure relates to a spinning electromotive assembly, e.g. an electric motor assembly, and to a method of operating a spinning electromotive assembly.

### BACKGROUND OF THE DISCLOSURE

The introduction of new wide bandgap power semiconductors (e.g., SiC, GaN) in motor inverters leads to higher pulse-width modulation, PWM, switching frequencies within the inverter and thus to higher electrical field strengths inside the motor coils resulting from higher dU/dt. As a result motor coils are exposed to partial discharges causing the so-called ‘corona effect’, which damages the motor coils' isolation over time and leads to complete motor failure if motor operation continues without any countermeasures taken. In the past PWM switching frequency of electrical drives was limited to a typical frequency range of 20 kHz to 40 kHz in order to avoid the negative impact of significant losses inside the power transistors during PWM switching. Therefore the issue of a corona effect on motor coils did not cause a real issue.

Modern condition monitoring solutions are predominately limited to current, noise and vibration measurements only (e.g., an isolation breakdown within neighbored windings inside a motor coils would be notable by a slightly increased phase current only). Detection of partial discharges, however, based on electric field measurements requires highly accurate motor models which do not exist until today (and are expected to consume significant computing power). As a conclusion, condition monitoring may be restricted to degradation effects, which have already started to cause damage to the motor itself.

There are also concepts to measure the impact of the corona effect by adding highly sensitive microphones to the motor housing to sense very small partial discharges or to sense for possible secondary such as ozone generation as a result of corona-effect-related discharges. Furthermore, significant effort is directed towards even more robust isolation coatings, which better withstand the increase in thermal stress of the partial discharges as part of the corona effect and the displacement of isolation material. However, there is a lack of concepts that allow early detection of the onset of the corona effect so that countermeasures can be taken at an early stage.

It is an object of the present disclosure to provide a spinning electromotive assembly and a method of operating a spinning electromotive assembly with improved corona effect detectability.

These objectives are achieved by the subject-matter of the independent claims. Further developments and embodiments are described in the dependent claims.

### SUMMARY OF THE DISCLOSURE

The following relates to an improved concept in the field of optical sensing of discharges, e.g. in an electric motor environment. One aspect relates to the integration of a sensor arrangement, e.g. for ultraviolet and/or spectral sensing, to reduce the impact of faster switching, e.g. of PWM related dU/dt, on an isolation material of a motor coil.

In at least one embodiment, a spinning electromotive assembly comprises a rotor, a stator, a control unit and an optical sensor arrangement. The rotor is rotatably supported by the stator and comprises motor coils. The control unit is electrically connected to the motor coils. Furthermore, the optical sensor arrangement is connected and/or assembled to the stator. In other words, the assembly comprises a spinning electromotive device, such as a generator or motor, and further components such as the optical sensor arrangement to form the spinning electromotive assembly.

During operation of the spinning electromotive assembly the control unit synchronously reverses the polarity of the motor coils. Thus, the rotor continuously rotates within the stator and generates a mechanical force in a constant direction of rotation. The optical sensor arrangement, connected to the stator, monitors the motor coils during operation of the spinning electromotive assembly. The optical sensor arrangement is operable to detect the electromagnetic radiation e.g. of a partial discharge induced in the motor coils when the polarity is synchronously reversed. The partial discharges may be detected by ultraviolet or ultraviolet and/or visible radiation induced in the motor coils when the polarity is reversed. In particular the partial discharges may be detected only by the ultraviolet radiation induced in the motor coils. In this case it is sufficient that the sensor arrangement is able to detect only UV radiation. This allows for the use of particularly cost-effective sensor arrangements.

The proposed concept allows for the integration of an optical sensor arrangement inside the stator part of a fast switched spinning electromotive device. This integration allows for effective measurements of partial discharges and/or a beginning corona effect on motor coils. Furthermore, integration can be made inside a housing, so even disturbing effects of ambient light, such as ultra-violet, UV, light originating from sunlight, or e.g. welding in close vicinity of the assembly, could be minimized or even excluded.

Moreover, adding an optical sensor arrangement to a spinning electromotive assembly is expected to improve robustness and lifespan. Partial discharges and-even worse-coils being exposed to the corona effect are two of the main reasons for isolation breakdown, which in turn is one of the main reasons for failure of an electric motor. For example, it is known that insulation temperatures exceeding a motor's rated value will cut the life of the insulation in half for every increase by 10° C.

A partial discharge constitutes a localized dielectric breakdown between two conductors of a small portion of an electrical insulation under high voltage stress. Such high voltages are commonly found in the motor coils of (fast) spinning electromotive devices. The partial discharge generates a plasma which irradiates electromagnetic radiation predominantly in the ultraviolet, UV, range. Hereinafter, UV light is considered to be electromagnetic radiation with wavelengths ranging from 10 nm to 400 nm, i.e. shorter than that of visible light. For example, partial discharges in motor coils can be characterized as twisted pairs of wires (making up the coils). Such pairs may show partial discharges with visible emission of visible light, e.g. apparent as a blue to violet glow in the air gap between the two wires. It has been found that a dominant emission due to partial discharge in a normal ambient air atmosphere lies in the range of 315 to 400 nm, i.e. ultraviolet A, or UV-A for short. However, depending on the actual geometry of the coils, e.g. distance of wires, emission can occur also in the ultraviolet B (UV-B) and even ultraviolet C (UV-C) range.

A corona discharge is usually revealed by a relatively steady glow or brush discharge in air. The corona effect on fast switched motor coils occurs only slowly (in the range of a couple of seconds to even minutes). The proposed concept allows to detect a beginning corona effect on the motor coils, e.g. inside the motor housing, using the optical sensor arrangement close to these coils, and allows for fast detection of the beginning harmful effect on isolation. Such advanced condition monitoring leads to better lifetime prediction and further optimized constructive margins, e.g. in motor design. For example, this allows for controlled overload operations in case of e.g. emergencies without the need to design with higher motor classes and allows for the usage of more cost efficient, smaller and/or lower weight motors.

The term “spinning electromotive device” or “spinning electromotive assembly” indicates that the proposed concept can be applied to different types of devices. For example, a spinning electromotive assembly may relate to an electric generator or to an electric motor. Electric motors operate through the interaction between the motor's magnetic field and electric current in a wire winding (motor coil) to generate torque applied on the motor's shaft. An electric generator is mechanically identical to an electric motor but operates with a reversed flow of power, converting mechanical energy into electrical energy. These devices can be powered by direct current (DC) sources, or by alternating current (AC) sources, such as inverters. The devices can be operated at constant or variable speeds, involving synchronously reversing the polarity of the motor coils.

In at least one embodiment, the optical sensor arrangement comprises at least one optical sensor which is operable to detect the electromagnetic radiation of the corona discharge. The optical sensors are operable to provide a detection signal which is indicative of the corona discharge. The optical sensors provide the detection signals as a unique indicator when a partial discharge or corona discharge has occurred.

In at least one embodiment, the optical sensors are arranged to detect electromagnetic radiation in the ultraviolet part of the electromagnetic spectrum. Typically, partial discharge or corona discharge show a characteristic emission in the ultraviolet, e.g. UV-A, range of the electromagnetic spectrum. Detectors which are sensitive in this range may provide a reliable detection signal which indicates that a partial discharge or corona discharge has occurred.

In at least one embodiment, the optical sensors are configured as optical spectral sensors arranged to provide the detection signal as a function of wavelength. Spectrally resolved detection signals enable immediate detection of beginning partial discharges or corona effect, e.g. by identification of characteristic spectral peaks such as in the UV-A/UV-B range.

In at least one embodiment, the optical sensors comprise analog-to-digital converters for processing the detection signals. The on-board analog-to-digital converters provide the detection signals in digital form, which forms a convenient basis for processing the detection signals as part of an integrated “in-assembly” monitoring or detection system for the spinning electromotive device.

For example, optical sensors are implemented as sensor modules. The optical sensors may comprise a low-profile package, such as a molded package. In an embodiment, the optical sensors comprise a number of optical channels distributed over the ultraviolet range or ultraviolet and visible range, e.g. channels dedicated to UV-A, UV-B and/or UV-C. The sensor modules allow for a compact design and efficient use of limited space in a spinning electromotive device, yet provide a spectral resolution sufficient to collect the detection signal with spectral information to enable highly reliable detection of discharges. For example, it is possible that the optical sensor arrangement comprises three-channel UV-A/B/C sensors. In this case the optical sensor arrangement in particular is free of cameras like digital cameras but only consists of one or more three-channel UV-A/B/C sensors.

In at least one embodiment, the stator comprises a set of two optical sensors for each motor coil. A reliable configuration comprises a set of two optical sensors, e.g. UV or spectral sensors, per coil in a multiphase spinning electromotive device, e.g. an electric motor. This leads to an overall set of at least six sensors per device to form the spinning electromotive assembly. Even higher counts can be implemented depending on the number of individual pole pairs, for example.

In at least one embodiment, the spinning electromotive assembly further comprises an acoustic sensor and/or a gas sensor operable to provide an additional detection signal indicative of the corona discharge.

The impact of partial discharges and/or the corona effect can also be measured (or monitored) by adding one or more acoustic sensors, such as microphones, or one or more gas sensors, such as ozone sensors, to the spinning electromotive assembly, e.g. to the motor housing. These additional sensors allow to sense very small partial discharges or to detect or sense for possible secondary effects such as ozone generation as a result of corona-effect-related discharges. The additional detection signals can be considered to further render the detection of discharge and corona effect even more robust and reliable.

The acoustic sensor, e.g. microphone, also allows to detect degraded motors as part of a condition monitoring to identify worn-out bearings (e.g. due to common mode effects, vibrations etc.). Gas sensors, such as ozone gas sensors, may account for longer time scale effects, as the corona effect would have existed for quite some time already before a sufficient amount of ozone is being generated. Hence, this can be considered sensing a secondary effect when it is too late to take proactive action. Thus, these sensors may add additional monitoring capability for longer scale effects and may complement the optical detection.

In at least one embodiment, the control unit comprises power switches. The power switches are operable to synchronously reverse the polarity of the motor coils according to a switching frequency determined by a control signal.

For example, the control signal is received by the control unit. In turn, the control unit controls a (variable) driving current or driving voltage which is applied to the motor coils. This control is altered according to the switching frequency (or switching rate) in order to rotate the rotor with respect to the stator. The switching is performed by means of the power switches under control of the control signal and results in a given speed or acceleration.

In at least one embodiment, the control unit is arranged to receive the control signal as a pulse-width modulated, PWM, control signal. As a consequence, the power switches are switched on or off in a series of pulses. To control the motor speed the control signal varies (modulates) the width of the pulses—hence the name pulse width modulation. In a practical control unit the power switches open and close at switching frequencies of 20 kHz and much higher.

In at least one embodiment, the power switches are operated with the switching frequency being much greater than 10 kHz, in particular greater than 40 kHz. In this range of switching frequencies motor coils are prone to discharge effects, such as the corona effect. The detection signals provided by the optical sensor arrangement, however, allow for such high switching rates, as negative effects due to discharge can be detected at an early stage and be prevented by countermeasures.

In at least one embodiment, the power switches are implemented as power MOSFETs, power transistors or similar, in particular, based on wide bandgap power semiconductors such as SiC or GaN. These switches allow for high switching frequencies much higher than the range of 20 kHz to 40 kHz.

In at least one embodiment, the assembly further comprises a processing unit. The processing unit is operable to adjust the synchronous reversing of polarity depending on one or more detection signals.

The processing unit can be a microcontroller, central processing unit, CPU, or a system-on-a-chip, SOC, and is dedicated to process the detection signals of the optical sensors, for instance. The detection signals contain information about beginning or occurring partial discharges or corona discharges in the motor coils. Thus, the processing unit may allow to implement countermeasures, e.g. to effect the switching frequency such that the discharges do not build up or break down.

In at least one embodiment, the processing unit is operable to provide the control signal depending on one or more detection signals. For example, the control signal to be provided to the control unit may be altered (for example, by way of PWM) so that the switching occurs with a lower switching frequency such that the discharges do not build up or break down.

In at least one embodiment, the processing unit determines a normal mode of operation or a safety mode of operation of the spinning electromotive assembly. In the normal mode of operation, the processing unit provides a first control signal according to a first switching frequency. For example, this first switching frequency is the intended switching frequency for a given application. In the safety mode of operation, the processing unit provides a second control signal, e.g. according to a reduced second switching frequency. The safety mode may be entered when a signal level, determined by one or more detection signals, reaches a pre-determined threshold level.

The corona effect on fast switched motor coils occurs only slowly (in the range of a couple of seconds to even minutes). The optical sensor arrangement allows to detect a beginning corona effect on the motor coils, e.g. inside the motor housing close to these coils before the beginning of harmful effects e.g. on isolation. Using the information of a beginning corona effect inside allows to adjust control by means of the control signal. For example, the control signal relies on an algorithmic PWM control of the motor drive. The safety mode of operation allows to shortly relax the switching characteristic to the reduced second switching frequency. As a consequence, harmful effects may collapse. After changing back to a more aggressive switching characteristic (normal mode of operation), the effect may gradually build up again. The short change of the switching characteristic is required only if a corona effect has been identified, e.g. as indicated by reaching the threshold level. Given the inertia of an electric motor, the hidden algorithmic change in switching characteristic would not even cause a notable motor rotation ripple.

Furthermore, a method of operating a spinning electromotive assembly is provided. The method comprises the steps of synchronously reversing the polarity of motor coils of a stator to rotate a rotor, and monitoring the motor coils by detecting electromagnetic radiation of a corona discharge induced in the motor coils when the polarity is synchronously reversed.

These steps can be complemented by further procedural steps, such as setting a normal mode of operation or a safety mode of operation of the spinning electromotive assembly.

Further embodiments of the method become apparent to the skilled reader from the aforementioned embodiments of the spinning electromotive assembly, and vice-versa.

Features described for the spinning electromotive assembly are disclosed for the method and vice-versa.

### BRIEF DESCRIPTION OF THE DRAWINGS

The following description of figures of exemplary embodiments may further illustrate and explain aspects of the improved concept. Components and parts with the same structure and the same effect, respectively, are marked with equivalent reference symbols. Insofar as components and parts correspond to one another in terms of their function in different figures, the description thereof is not necessarily repeated for each of the following figures.

In the Figures:

FIG. 1 shows an exemplary embodiment of a spinning electromotive assembly with an optical sensor arrangement,

FIG. 2 shows an exemplary embodiment of a motor coil,

FIG. 3 shows an exemplary spectrum of a partial discharge, and

FIG. 4 shows an exemplary embodiment of a spinning electromotive assembly with an acoustical sensor arrangement and a gas sensor arrangement.

### DETAILED DESCRIPTION

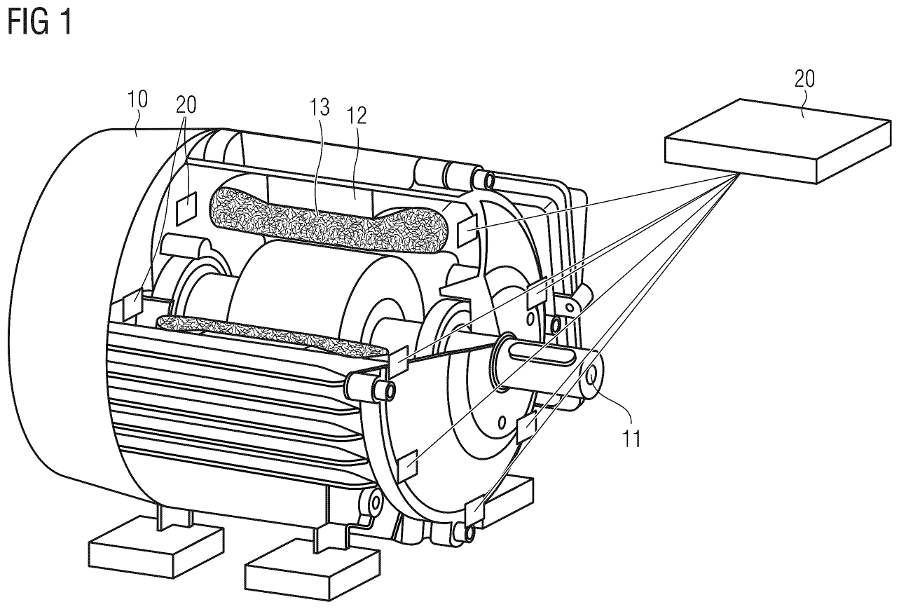

FIG. 1 shows an exemplary embodiment of a spinning electromotive assembly with an optical sensor arrangement. This example illustrates an electrical motor assembly, which is one possible embodiment of a spinning electromotive assembly. The assembly comprises a housing 10 which accommodates a rotor 11 and a stator 12. The rotor is rotatably supported by the stator. The stator is immobile and includes several windings or motor coils.

The optical sensor arrangement is assembled at the stator 12 with a field-of-view focusing on the coils. That is to say the optical sensor arrangement is mechanically and/or electrically connected to the stator 12. This may include also positions within the housing 10 which are not rotating parts of the electrical motor. Basically, the optical sensor arrangement is arranged in a way that a field-of-view includes, directly or indirectly, the motor coils. This way, electromagnetic radiation generated at or close to the motor coils 13 may strike the optical sensor arrangement and is eventually detected as a respective detection signal. Thus, the detection signal, or detection signals, is/are indicative of a corona discharge induced in the motor coils when the polarity is synchronously reversed, for example.

The optical sensor arrangement comprises a number of optical sensors 20. In this exemplary embodiment, the arrangement comprises a set of two optical sensors per phase of a multiphase electrical motor. This leads to two sets of six sensors. Each set of optical sensors is located at a first and a second side of the stator 12, opposite the respective ends of the rotor 11. Even higher counts can be implemented depending on the number of individual pole pairs, for example.

The optical sensors 20 can be implemented as ultraviolet sensitive sensors and/or as spectral sensors. For example, the optical sensors are compact sensor modules which comprise one or more optical channels distributed over a range of electromagnetic wavelengths, or ranges of electromagnetic wavelengths. The optical channels allow detection according to a respective wavelength or a wavelength band, such as visible light or ultraviolet bands, UV-A, UV-B, or UV-C. Thus, the generated detection signal(s) can be attributed to a characteristic wavelength or wavelength band.

Furthermore, the sensor modules comprise further electronic components for pre-processing of the detection signals. These further electronic components comprise dedicated parallel ADCs (not shown) for converting the detection signals into digital form. Further electronic components may include terminals to receive control signals and to provide the detection signals to a processing unit (not shown).

The processing unit is arranged in the spinning electromotive assembly, e.g. inside the housing 10. The processing unit is electrically and operatively connected to the optical sensor arrangement and, thus, to the plurality of optical sensors 20. By way of this connection, the processing unit receives the detection signals, which, in turn, can be processed by the processing unit.

The processing unit is also arranged to generate a control signal. A control unit is arranged in the spinning electromotive assembly, e.g. inside the housing, and is electrically and operatively connected to the processing unit. By way of this connection, the processing unit provides the control signal to the control unit (not shown). The control unit operates the spinning electromotive assembly depending on said control signal. For example, the control unit comprises power switches to drive the motor coils 13 in order to have the rotor 11 rotate with respect to the stator 12. Typically, the control signal is pulse-width modulated and the power switches drive the motor coils with defined switching frequencies.

The processing unit determines the switching frequencies depending on the received detection signals. Depending on the detection signals, the processing unit initiates a normal mode of operation or a safety mode of operation of the spinning electromotive assembly.

In the normal mode of operation, the processing unit provides a first control signal according to a first switching frequency. For example, this first switching frequency is the intended switching frequency for a given application. In the safety mode of operation, the processing unit provides a second control signal, e.g. according to a reduced second switching frequency. The safety mode may be entered when a signal level, determined by one or more detection signals, reaches a pre-determined threshold level.

The pre-determined threshold level accounts for possible discharges, e.g. including the corona effect. Partial discharges and corona effect may be found to show specific spectral characteristics which allow to identify these effects by way of the detection signals. The pre-determined threshold levels can be recorded using the optical sensor arrangement by way of calibration or can be set to expected values. For example, the discharges occur to a certain extent in the UV-A. The optical sensors 20 may detect the UV-A with a given sensitivity, e.g. by way of a dedicated optical channel. Once a certain signal level has been reached, or is detected by said optical sensor (e.g., the dedicated optical channel), the signal level is evaluated in terms of the respective threshold value by means of the processing unit. Then, the processing unit terminates the normal mode of operation and enters the safety mode of operation. The processing unit may also account for a pre-determined period of time, so that the signal level additionally has to exceed this period of time until the increased signal level causes the safety mode of operation. For example, during the safety mode of operation the control signal is set to lower the switching frequencies to a level where the signal level(s) of the detection signal(s) drop(s) below the threshold. The processing unit may also account for another pre-determined period of time, so that the signal level additionally has to exceed this period of time until the decreased signal level causes the safety mode of operation to terminate.

The corona effect on fast switched motor coils occurs only slowly (in the range of a couple of seconds to even minutes). The optical sensor arrangement allows to detect a beginning corona effect on the motor coils 13, e.g. inside the motor housing 10 close to these coils before the beginning of harmful effects on the isolation. Using the information of a beginning corona effect inside allows to adjust control by means of the control signal. For example, the control signal relies on an algorithmic PWM control of the motor drive. The safety mode of operation allows to shortly relax the switching characteristic to the reduced second switching frequency. As a consequence, harmful effects may collapse. After changing back to a more aggressive switching characteristic (normal mode of operation), the effect may gradually build up again. The short change of the switching characteristic is required only if a corona effect has been identified, e.g. as indicated by reaching the threshold level. Given the inertia of an electric motor, the hidden algorithmic change in switching characteristic would not even cause a notable motor rotation ripple.

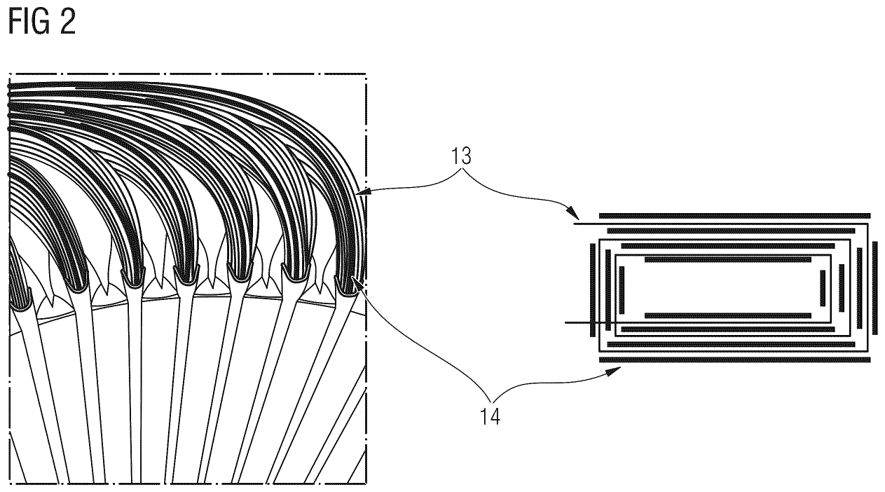

FIG. 2 shows an exemplary embodiment of a motor coil. The motor coils 13 constitute electrical conductors that comprise a series of conductive wires wrapped around a pole. Due to the wrapping of wires, sections of the wire come into close vicinity to each other. The wires are isolated in order to prevent short circuits. Continuous switching of driving currents and/or voltages lead to high voltages between the windings of the coils. In fact, switching frequencies>>10 kHz and higher voltages could lead to partial discharges and/or corona discharge (indicated in the drawing) on the motor coils, causing sudden motor failure as a result of isolation breakdown. Continuous measurement by means of the optical sensor arrangement, e.g. by monitoring parts of the UV spectrum, enables immediate detection of beginning partial discharges by identification of characteristic spectral levels, e.g. by peaks in UV-A/-B range.

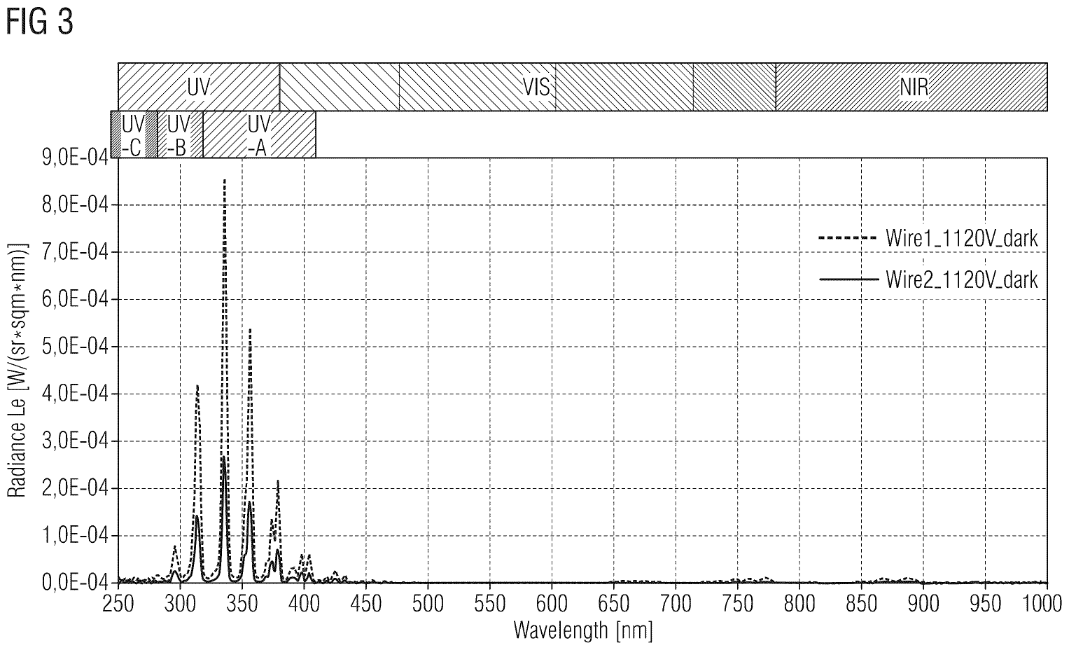

FIG. 3 shows an exemplary spectrum of a partial discharge. The graph shows a spectral characterization of partial discharges as radiance as a function of wavelength. This data has been recorded using a model system. The model system comprises a twisted pair of isolated wires. Two different types of wire were used, coated with different insulation materials. The twisted pairs were accessible from the side. Partial discharges were induced and visible as a blue to violet glow in the air gap between the two wires. Optical sensors 20 were directed to one of the sections. Ambient light was reduced. Tests have been performed in a normal air atmosphere.

The graph shows characteristic peaks located predominantly in the UV-A range, with minor contributions in the UV-B and UV-C ranges, and even less pronounced in the visible range. Thus, the measured radiance is primarily within the UV-A spectrum. It has been found that the radiance is dependent on further parameters, including isolation materials on the wires and their distance from each other. A peak amplitude changes with voltage. These measurements on the model system allow to determine the threshold levels discussed above.

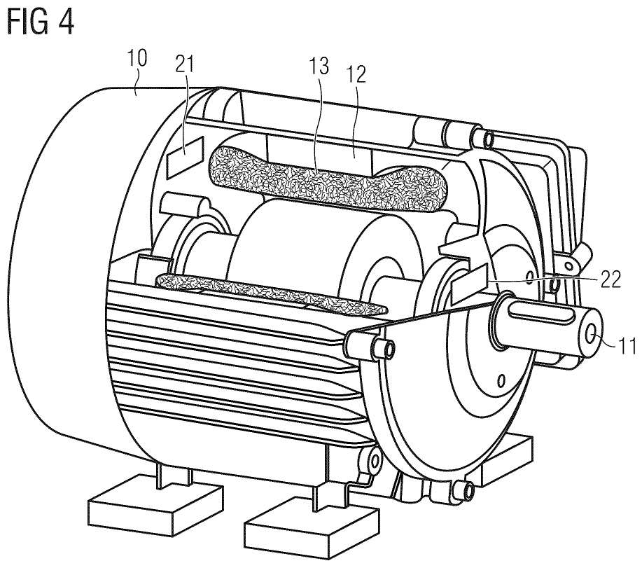

FIG. 4 shows an exemplary embodiment of a spinning electromotive assembly with an acoustical sensor arrangement and a gas sensor arrangement. The additional sensors are also connected to the stator 12, such that measurements of acoustics and gas are possible within the housing. The acoustical sensor arrangement comprises a microphone 21 to detect sound levels due to discharges. The gas sensor arrangement comprises an ozone gas sensor 22 to detect ozone generation as a result of the corona effect/partial discharges only as a secondary effect. Once it becomes detectable, the coils have been exposed to the harmful effect for some time already.

While this specification contains many specifics, these should not be construed as limitations on the scope of the invention or of what may be claimed, but rather as descriptions of features specific to particular embodiments of the invention. Certain features that are described in this specification in the context of separate embodiments can also be implemented in combination in a single embodiment. Conversely, various features that are described in the context of a single embodiment can also be implemented in multiple embodiments separately or in any suitable sub-combination. Moreover, although features may be described above as acting in certain combinations and even initially claimed as such, one or more features from a claimed combination can in some cases be excised from the combination, and the claimed combination may be directed to a sub-combination or variation of a sub-combination.

Similarly, while operations are depicted in the drawings in a particular order, this should not be understood as requiring that such operations be performed in the particular order shown or in sequential order, or that all illustrated operations be performed, to achieve the desirable results. In certain circumstances, multitasking and parallel processing may be advantageous.

This patent application claims the priority of German patent application 10 2022 109 676.9, the disclosure content of which is hereby incorporated by reference.

### REFERENCES

10 housing
11 rotor
12 stator
13 motor coils
14 corona effect
20 optical sensor
21 microphone
22 gas sensor

1. A spinning electromotive assembly, comprising:
a rotor, rotatably supported by a stator and comprising motor coils,
a control unit operable to synchronously reverse the polarity of the motor coils, and
an optical sensor arrangement assembled to the stator and operable to detect ultraviolet or ultraviolet and/or visible radiation of partial discharges induced in the motor coils when the polarity is reversed.

2. The assembly according to claim 1, wherein the optical sensor arrangement comprises optical sensors operable to detect the electromagnetic radiation of the corona discharge and operable to provide a detection signal indicative of the corona discharge.

3. The assembly according to claim 2, wherein the optical sensors are arranged to detect electromagnetic radiation in the ultraviolet part of the electromagnetic spectrum.

4. The assembly according to claim 2, wherein the optical sensors are configured as optical spectral sensors arranged to provide the detection signal as a function of wavelength.

5. The assembly according to claim 2, wherein the optical sensors comprise analog-to-digital converters for processing the detection signals.

6. The assembly according claim 2, wherein the stator comprises a set of two optical sensors for each motor coil.

7. The assembly according to claim 1, further comprising an acoustic sensor and/or a gas sensor operable to provide an additional detection signal indicative of the corona discharge.

8. The assembly according to claim 1, wherein
the control unit comprises power switches, and
the power switches are operable to synchronously reverse the polarity of the motor coils according to a switching frequency determined by a control signal.

9. The assembly according to claim 7, wherein the control unit is arranged to receive a control signal as a pulse-width modulated control signal.

10. The assembly according to claim 7, wherein the power switches are operated with the switching frequency being much greater than 10 kHz, in particular greater than 40 kHz.

11. The assembly according to claim 8, wherein the power switches are implemented as power MOSFETs, in particular, based on wide bandgap power semiconductors such as SiC or GaN.

12. The assembly according to claim 1, further comprising a processing unit, wherein the processing unit is operable to adjust the synchronous reversing of polarity depending on one or more detection signals.

13. The assembly according to claim 12, wherein the processing unit is operable to provide a control signal depending on one or more detection signals.

14. The assembly according to claim 12, wherein the processing unit:
in a normal mode of operation, provides a first control signal according to a first switching frequency,
in a safety mode of operation, provides a second control signal according to a reduced second switching frequency, wherein the safety mode is entered when a signal level determined by one or more detection signals reaches a pre-determined threshold level.

15. Method of operating a spinning electromotive assembly, the method comprising the steps of:
synchronously reversing the polarity of motor coils of a stator to rotate a rotor, and
monitoring the motor coils by detecting electromagnetic radiation of a corona discharge induced in the motor coils when the polarity is synchronously reversed.

16. A spinning electromotive assembly, comprising:
a rotor, rotatably supported by a stator and comprising motor coils,
a control unit operable to synchronously reverse the polarity of the motor coils,
an optical sensor arrangement assembled to the stator and operable to detect ultraviolet or ultraviolet and/or visible radiation of partial discharges induced in the motor coils when the polarity is reversed, and
a processing unit, wherein the processing unit is operable to adjust the synchronous reversing of polarity depending on one or more detection signals that contain information about beginning or occurring partial discharges or corona discharges in the motor coils.
